(19) United States
(12) Patent Application Publication
(10) Pub. No.: US 2004/0047225 A1
(43) Pub. Date: Mar. 11, 2004

(54) Semiconductor device having shared sense amplifier configuration

(75) Inventor: Goro Hayakawa, Hyogo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/352,071

(22) Filed: Jan. 28, 2003

(30) Foreign Application Priority Data
Sep. 10, 2002 (JP) 2002-264193(P)

(51) Int. Cl. G11C 8/00

(52) U.S. Cl. 365/230.03

(57) ABSTRACT

A timing circuit has a bit line isolation signal input from one input terminal, and controls a timing to output the bit line isolation signal to a memory mat using an external signal input from the other input terminal. Thus, by controlling an operation timing of the bit line isolation signal with the external signal, an effect of a short circuit of a word line and a bit line caused on one memory cell array will be communicated also to the other memory cell array, and a defective bit line on the opposite sides of a shared sense amplifier can be detected.

### BACKGROUND OF THE INVENTION

1. Field of the Invention

The present invention relates to a semiconductor device, and more particularly to a semiconductor device having a shared sense amplifier configuration.

2. Description of the Background Art

In many cases, for higher integration of a memory cell array, a semiconductor device, particularly a DRAM (Dynamic Random Access Memory), has a shared sense amplifier configuration in which each bit line pair in a plurality of memory cell arrays is shared by a common sense amplifier.

FIG. 5 is a schematic block diagram showing a configuration of a conventional DRAM having the shared sense amplifier configuration.

First, an overall configuration and operation of the DRAM will be described. Referring to FIG. 5, the DRAM includes an internal power supply potential (intVCC) generating circuit 1, a clock generating circuit 2, a row and column address buffer 3, a row decoder 4, a redundant row decoder 5, a column decoder 6, a memory mat 7, an input buffer 11, and an output buffer 12. Memory mat 7 includes a memory array 8, a redundant memory array 9, and a sense amplifier+input/output control circuit 10.

Internal power supply potential generating circuit 1 receives power supply potential VCC and ground potential GND from the outside, and generates internal power supply potential intVCC lower than external power supply potential VCC, which is in turn provided to the entire DRAM. Internal power supply potential intVCC can be tuned by a fuse group provided within internal power supply potential generating circuit 1. Clock generating circuit 2 selects a prescribed operation mode in response to signals /RAS, /CAS externally provided, and controls the entire DRAM.

Row and column address buffer 3 generates row address signals RA0-RAi and column address signals CA0-CAi based on address signals A0-Ai (i is an integer not smaller than 0) externally provided. Generated signals RA0-RAi and CA0-CAi are provided to row decoders 4, 5 and column decoder 6 respectively.

Memory array 8 includes a plurality of memory cells arranged in matrix and each storing 1-bit data. Each memory cell is arranged at a prescribed address determined by a row address and a column address.

Row decoder 4 designates a row address of memory array 8 in response to row address signals RA0-RAi provided from row and column address buffer 3. In redundant row decoder 5, a fuse group is provided for programming a row address including a defective memory cell in memory array 8 and a row address in redundant memory array 9 to be replaced with the former row address. When row address signals RA0-RAi corresponding to the defective row address programmed by the fuse group are input, row decoder 4 does not designate that row address, and instead of that row address, redundant row decoder 5 designates the programmed row address in redundant memory array 9. In other words, the defective memory cell row including the defective memory cell in memory array 8 is replaced with a normal memory cell row in redundant memory array 9.

Column decoder 6 designates a column address of memory array 8 in response to column address signals CA0-CAi provided from row and column address buffer 3. Sense amplifier+input/output control circuit 10 connects a memory cell at an address designated by row decoder 4 (or redundant row decoder 5) and column decoder 6 to one end of a data input/output line pair IOP. The other end of data input/output line pair IOP is connected to input buffer 11 and output buffer 12. Input buffer 11, in a write mode, provides data Dj externally input through a DQj terminal (j is a natural number) to the memory cell selected via data input/output line pair IOP, in response to a signal /WE externally provided. Output buffer 12, in a read mode, outputs to the outside read data Qj from the selected memory cell through DQj terminal, in response to a signal /OE externally input.

FIG. 6 is a circuit diagram showing a circuit configuration of memory mat 7 in the conventional DRAM having the shared sense amplifier configuration shown in FIG. 5. Note that some components which are not directly relevant to the description are not shown.

As shown in FIG. 6, memory mat 7 includes a sense amplifier 100, N-channel MOS transistors 101-104, a bit line equalizer 108, memory cells 109, 110 constituting a part of not-shown one memory cell array (hereinafter, referred to as a “memory cell array a”), and memory cells 111, 112 constituting a part of not-shown the other memory cell (hereinafter, referred to as a “memory cell array b”).

Sense amplifier 100 is connected between a bit line pair ZBLa, BLa on a side of memory cell array a and a bit line pair ZBLb, BLb on a side of memory cell array b, and amplifies a potential difference of a data signal read from the memory cell to a bit line to power supply potential Vcc in response to sense amplifier activating signals S0N, ZS0P.

N-channel MOS transistors 101, 102 electrically connect/isolate bit line pair ZBLa, BLa to/from sense amplifier 100 in response to a bit line isolation signal BLIa. N-channel MOS transistors 103, 104 electrically connect/isolate bit line pair ZBLb, BLb to/from sense amplifier 100 in response to a bit line isolation signal BLIb.

Bit line equalizer 108 includes N-channel MOS transistors 105, 106 and 107. N-channel MOS transistors 105, 106 are rendered conductive in response to a bit line equalizing signal BLEQ, and couple bit line pair ZBLa, BLa to a bit line potential VBL. N-channel MOS transistor 107 is rendered conductive also in response to bit line equalizing signal BLEQ, and connects one of bit lines, that is, ZBLa (including ZBLb), to the other, that is, BLa (including BLb). In other words, in response to bit line equalization signal BLEQ, bit line equalizer 108 equalizes the potentials of bit line pair ZBLa, BLa and bit line pair ZBLb, BLb with bit line potential VBL (=Vcc/2 (Vcc indicates intVCC)).

Memory cells 109-112 are selected by word lines WLa+1, WLa, WLb, WLb+1 respectively. In memory cells 109, 110 and memory cells 111, 112, data signals are read through bit line BLa and bit line BLb respectively. Here, respective memory cells 109-112 have a well-known configuration, in which a capacitor for information storage having one end fixed to a cell plate potential VCP, and an N-channel MOS transistor for access are included. In FIG. 6, a word line WLb and bit line BLb on the side of memory cell array b are electrically short-circuited.

FIG. 7 is a timing diagram illustrating an operation of sense amplifier 100 sensing memory cell 110 contained in memory cell array a. Here, it is assumed that H level is written in memory cell 110.

At time t1, when a row address strobe signal ZRAS is set from H level to L level, in response to this, bit line equalizing signal BLEQ is set from H level to L level at time t2. When bit line equalizing signal BLEQ attains L level, equalization of bit line pair ZBLa, BLa of which potential has been equalized with bit line potential VBL (=Vcc/2) till then is cancelled.

In response to L level of bit line equalizing signal BLEQ, at time t3, bit line isolation signal BLIb is set from H level to L level. When bit line isolation signal BLIb attains L level, a pair of bit lines ZBLb, BLb are electrically isolated from sense amplifier 100. Therefore, an effect of a short-circuit of word line WLb and bit line BLb is not communicated to memory cell array a. Here, since bit line isolation signal BLIa maintains H level, the pair of bit lines ZBLa, BLa are constantly electrically connected to sense amplifier 100.

In response to L level of bit line isolation signal BLIb, at time t4, word line WLa is activated from L level to H level. When word line WLa is activated, memory cell 110 is selected. In response to the data signal read from memory cell 110, the potential of bit line BLa is raised.

On the other hand, when word line WLa is activated, sense amplifier activating signal S0N is activated from L level to H level at time t5, and sense amplifier activating signal ZS0P is activated from H level to L level at time t6, respectively. Sense amplifier 100 is thus activated, and the potential difference between bit lines BLa and ZBLa due to the data signal read from memory cell 110 is amplified to power supply potential Vcc. The data signal read from memory cell 110 is amplified, and the pair of bit lines BLa and ZBLa attain H level and L level respectively.

As described above, in the conventional DRAM having the shared sense amplifier configuration, even when a short-circuit of word line WLb and bit line BLb on the side of memory cell array b is caused, the effect thereof is not communicated to memory cell array a if it is not significant. Therefore, in the conventional DRAM, a defective bit line is detected through a test only on the side of memory cell array b where the short-circuit has been caused, and not on the side of memory cell array a.

Accordingly, when the defective bit line is repaired by a unit of a memory cell array, only the bit line on the side of memory cell array b where a defect is present was replaced by a spare column, and the bit line on the side of memory cell array a was not replaced by the same.

If the short-circuit of word line WLb and bit line BLb is more significant because of an electrical stress caused, for example, by burn-in in the test, bit line potential VBL is pulled toward a ground level, and will be lower than Vcc/2.

When the data signal read from the memory cell on the side of memory cell array a is sensed while the bit line level is low, a sense margin with respect to L level of the memory cell in the memory cell array a which was not replaced by the spare column is reduced, and a defect is caused.

### SUMMARY OF THE INVENTION

An object of the present invention is to provide a semiconductor device, in which an effect of a short-circuit of a word line and a bit line caused on a side of one memory cell array will be communicated to the other memory cell array, and a defective bit line on opposite sides of a shared sense amplifier can be detected.

A semiconductor device according to the present invention includes a first memory cell array and a second memory cell array. The first memory cell array includes a first memory cell group arranged in matrix, a first word line group arranged corresponding to a row of the first memory cell group and each having a memory cell in a corresponding row connected, and a first bit line pair arranged corresponding to a column of the first memory cell group and each having a memory cell in a corresponding column connected. The second memory cell array includes a second memory cell group arranged in matrix, a second word line group arranged corresponding to a row of the second memory cell group and each having a memory cell in a corresponding row connected, and a second bit line pair arranged corresponding to a column of the second memory cell group and each having a memory cell in a corresponding column connected. In addition, the semiconductor device according to the present invention includes a sense amplifier shared by the first and second bit line pairs, a bit line equalizing circuit initializing a potential of the first and second bit line pairs, a first isolating gate circuit switching a connected/isolated state between the first bit line pair and the sense amplifier, a second isolating gate circuit switching a connected/isolated state between the second bit line pair and the sense amplifier, and a control circuit allowing isolation of the first or the second bit line pair from the sense amplifier by the first or the second isolating gate circuit a certain time after a bit line equalizing operation by the bit line equalizing circuit is cancelled.

Therefore, according to the present invention, the bit line pair is isolated from the sense amplifier by the isolating gate circuit a certain time after the bit line equalizing operation by the bit line equalizing circuit is cancelled. Thus, the effect of the short-circuit of the word line and the bit line caused on the side of one memory cell array is communicated to the other memory cell array, and a defective bit line on the opposite sides of a shared sense amplifier can be detected.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic block diagram showing a configuration of a DRAM having a shared sense amplifier configuration according to a first embodiment.

FIG. 2 is a timing diagram illustrating an operation of a sense amplifier 100 sensing a memory cell 110 contained in a memory cell array a in the first embodiment.

FIG. 3 is a schematic block diagram of a DRAM having a shared sense amplifier configuration according to a second embodiment.

FIG. 4 is a timing diagram illustrating an operation of sense amplifier 100 sensing memory cell 110 contained in memory cell array a in the second embodiment.

FIG. 5 is a schematic block diagram showing a configuration of a conventional DRAM having a shared sense amplifier configuration.

FIG. 6 is a circuit diagram showing a circuit configuration of a memory mat 7 in the conventional DRAM having the shared sense amplifier configuration shown in FIG. 5.

FIG. 7 is a timing diagram illustrating an operation of sense amplifier 100 sensing memory cell 110 contained in memory cell array a.

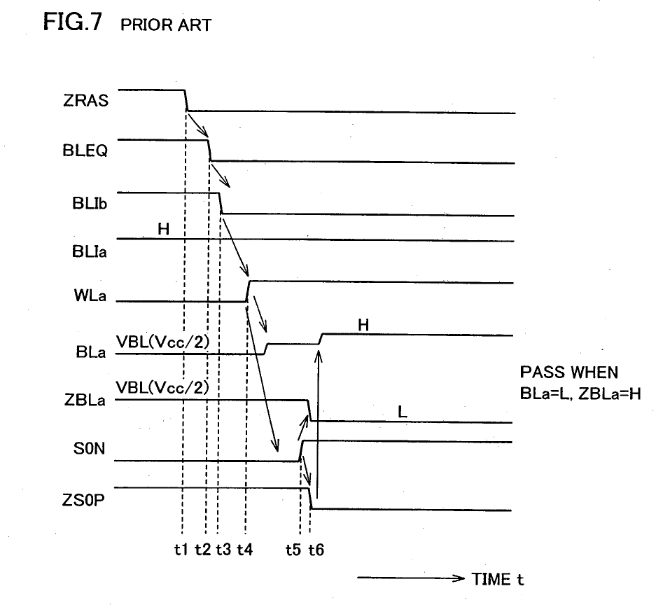

### DESCRIPTION OF THE PREFERRED EMBODIMENTS

In the following, embodiments of the present invention will be described in detail with reference to the figures. It is noted that the same reference characters refer to the same or corresponding components in the figures.

(First Embodiment)

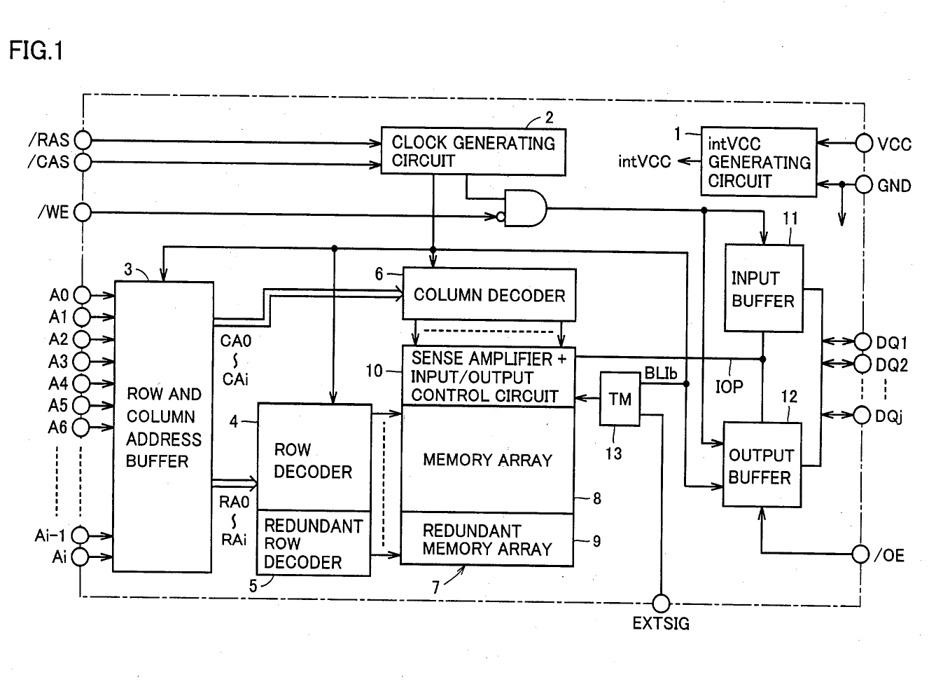

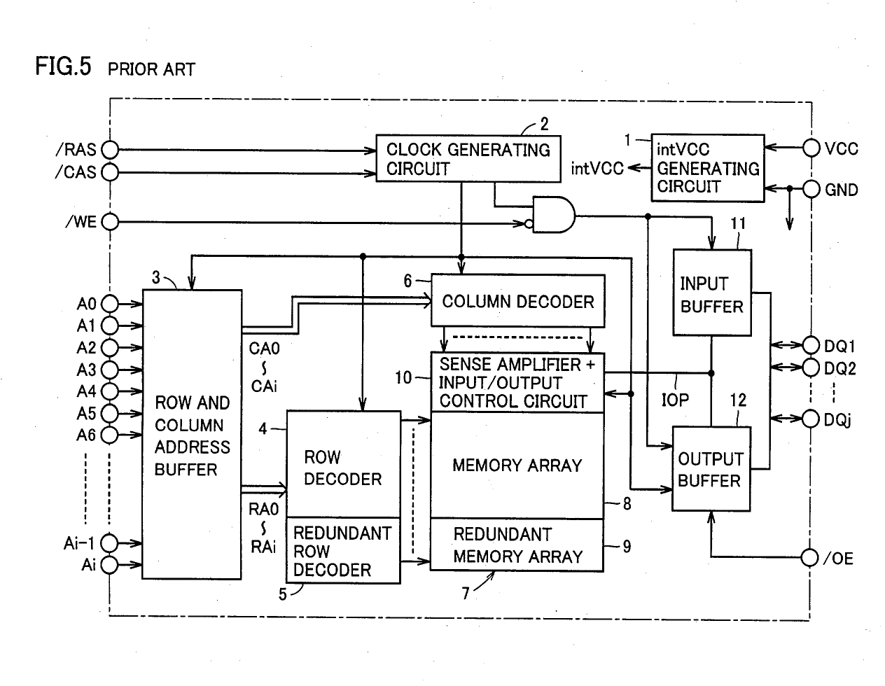

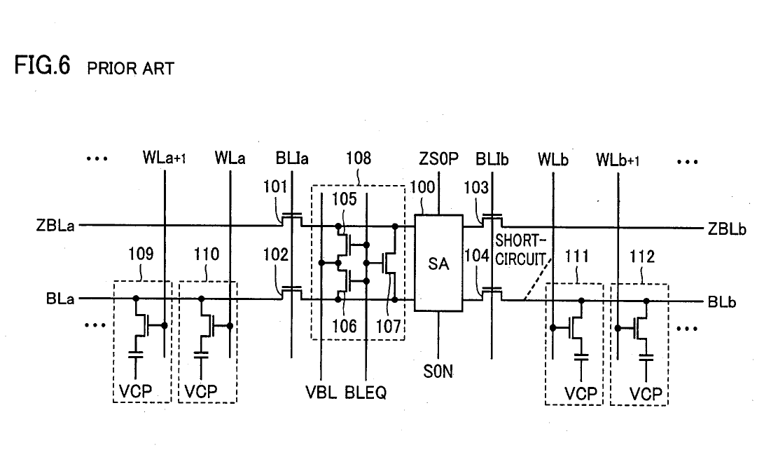

A DRAM of the first embodiment shown in FIG. 1 has a configuration in which a timing circuit 13 controlling an operation timing of a bit line isolation signal with an external signal is added to the conventional DRAM shown in FIG. 5. Here, since a circuit configuration of memory mat 7 in the DRAM of the first embodiment is the same as in FIG. 6, illustration and description thereof will not be repeated.

Timing circuit 13 has the bit line isolation signal input from one input terminal, and controls a timing to output the bit line isolation signal to memory mat 7, using an external signal EXTSIG input from the other input terminal (an external row address strobe signal EXTZRAS in a SDR DRAM (Single Data Rate DRAM), for example).

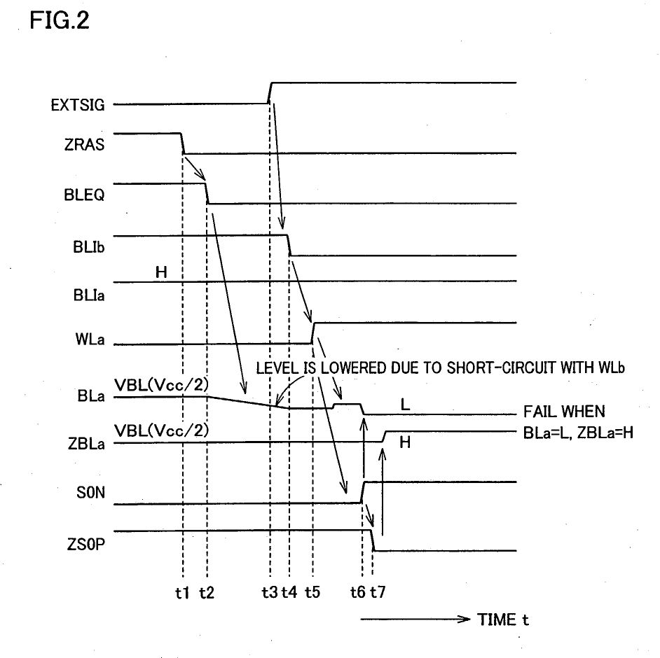

Adapted to subsequent description for FIG. 2, BLIb is shown as the bit line isolation signal in FIG. 1. It is to be noted, however, that BLIa is also possible. Moreover, though detailed illustration is not provided here for the sake of convenience, a signal input from clock signal generating circuit 2 to memory mat 7 is not limited to the bit line isolation signal.

FIG. 2 is a timing diagram illustrating an operation of sense amplifier 100 sensing memory cell 110 contained in memory cell array a in the first embodiment, with reference to FIG. 6. Here, it is assumed that H level is written in memory cell 110.

At time t1, when row address strobe signal ZRAS is set from H level to L level, in response to this, bit line equalizing signal BLEQ is set from H level to L level at time t2. When bit line equalizing signal BLEQ attains L level, equalization of bit line pair ZBLa, BLa of which potential has been equalized with bit line potential VBL (=Vcc/2) till then is cancelled.

Even after equalization of bit line pair ZBLa, BLa is cancelled, bit line isolation signal BLIb remains at H level until time t4. Therefore, the level of bit line BLa is gradually lowered from time t2 to t4 due to the effect of the short circuit of word line WLb and bit line BLb.

On the other hand, at time t3, when external signal EXTSIG is set from L level to H level, in response to this, bit line isolation signal BLIb is set from H level to L level at time t4.

When bit line isolation signal BLIb attains L level, the pair of bit lines ZBLb, BLb are electrically isolated from sense amplifier 100. Therefore, the level of bit line BLa that was gradually lowered due to the effect of the short-circuit of word line WLb and bit line BLb till then will be stabilized. As bit line isolation signal BLIA maintains H level, the pair of bit lines ZBLa, BLa are constantly electrically connected to sense amplifier 100.

In response to L level of bit line isolation signal BLIb, word line WLa is activated from L level to H level at time t5. When word line WLa is activated, memory cell 110 is selected. Upon receiving the data signal read from memory cell 110, the potential of bit line BLa is raised. The potential of bit line ZBLa, however, is higher than that of bit line BLa even after the potential of BLa has been raised. This is because the level of bit line BLa has gradually been lowered from time t2 to t4.

Meanwhile, when word line WLa is activated, sense amplifier activating signal S0N is activated from L level to H level at time t6, and sense amplifier activating signal ZS0P is activated from H level to L level at time t7, respectively. Though sense amplifier 100 is thus activated, the potential of bit line ZBLa is higher than that of bit line BLa. Therefore, the potential difference between bit lines ZBLa and BLa is amplified to power supply potential Vcc with a polarity reverse to the data signal read from memory cell 110. Thus, the pair of bit lines BLa, ZBLa are amplified with the polarity reverse to the data signal read from memory cell 110, and attain L level and H level respectively.

As described above, in the DRAM of the first embodiment, when word line WLb and bit line BLb are short-circuited on the side of memory cell array b, the effect thereof will be communicated to memory cell array a. Therefore, in the DRAM of the first embodiment, a defective bit line is detected not only on the side of memory cell array b where the short-circuit has been caused but also on the side of memory cell array a through a test.

Thus, according to the first embodiment, by controlling an operation timing of the bit line isolation signal with an external signal, the effect of the short-circuit of the word line and the bit line caused on the side of one memory cell array will be communicated to the other memory cell array, and the defective bit line on the opposite sides of the shared sense amplifier can be detected.

(Second Embodiment)

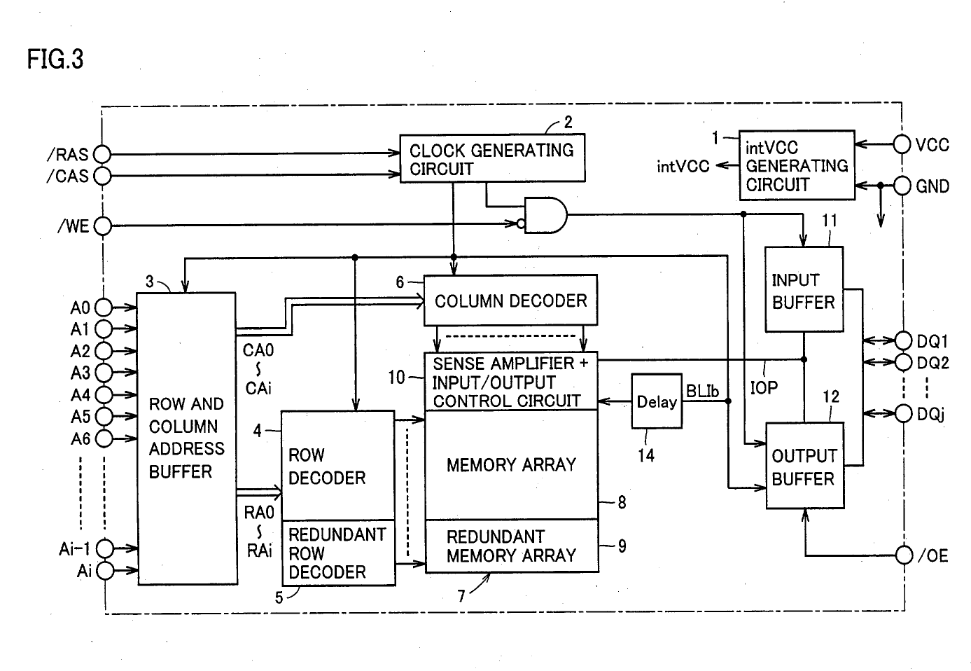

A DRAM of the second embodiment shown in FIG. 3 has a configuration in which an internal delay circuit 14 delaying the bit line isolation signal is added to the conventional DRAM shown in FIG. 5. Here, since a circuit configuration of memory mat 7 in the DRAM of the second embodiment is the same as in FIG. 6, illustration and description thereof will not be repeated.

Internal delay circuit 14, in a special test mode entry, delays the bit line isolation signal input from an input terminal, which is in turn output to memory mat 7.

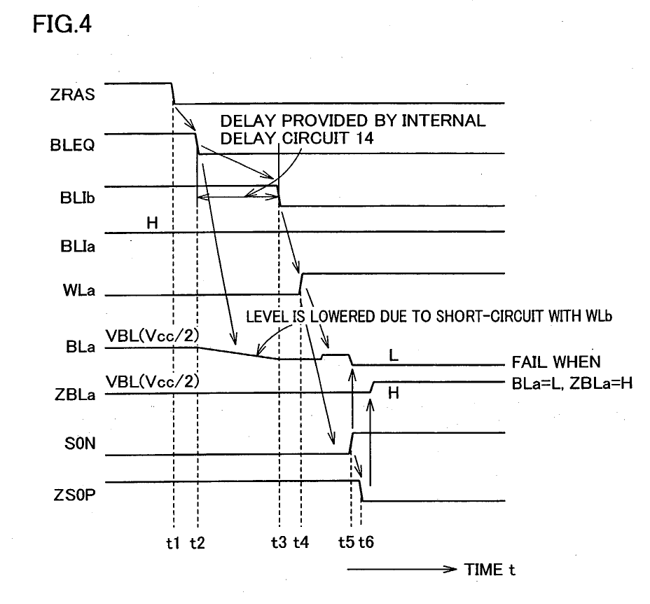

Adapted to subsequent description for FIG. 4, BLIb is shown as the bit line isolation signal in FIG. 3. It is to be noted, however, that BLIa is also possible. Moreover, though detailed illustration is not provided here for the sake of convenience, a signal input from clock signal generating circuit 2 to memory mat 7 is not limited to the bit line isolation signal.

FIG. 4 is a timing diagram illustrating an operation of sense amplifier 100 sensing memory cell 110 contained in memory cell array a in the second embodiment, with reference to FIG. 6. Here, it is assumed that H level is written in memory cell 110.

At time t1, when row address strobe signal ZRAS is set from H level to L level, in response to this, bit line equalizing signal BLEQ is set from H level to L level at time t2. When bit line equalizing signal BLEQ attains L level, equalization of bit line pair ZBLa, BLa of which potential has been equalized with bit line potential VBL (=Vcc/2) till then is cancelled.

Even after equalization of bit line pair ZBLa, BLa is cancelled, bit line isolation signal BLIb remains at H level until time t4. Therefore, the level of bit line BLa is gradually lowered from time t2 to t3 due to the effect of the short-circuit of word line WLb and bit line BLb.

On the other hand, by an action of internal delay circuit 14, bit line isolation signal BLIb is set from H level to L level at time t3, that is, a certain time after bit line equalizing signal BLEQ falls at time t2.

When bit line isolation signal BLIb attains L level, the pair of bit lines ZBLb, BLb are electrically isolated from sense amplifier 100. Therefore, the level of bit line BLa that was gradually lowered due to the effect of the short-circuit of word line WLb and bit line BLb till then will be stabilized. As bit line isolation signal BLIa maintains H level, the pair of bit lines ZBLa, BLa are constantly electrically connected to sense amplifier 100.

In response to L level of bit line isolation signal BLIb, word line WLa is activated from L level to H level at time t5. When word line WLa is activated, memory cell 110 is selected. Upon receiving the data signal read from memory cell 110, the potential of bit line BLa is raised. The potential of bit line ZBLa, however, is higher than that of bit line BLa even after the potential of BLa has been raised. This is because the level of bit line BLa has gradually been lowered from time t2 to t3.

Meanwhile, when word line WLa is activated, sense amplifier activating signal S0N is activated from L level to H level at time t5, and sense amplifier activating signal ZS0P is activated from H level to L level at time t6, respectively. Though sense amplifier 100 is thus activated, the potential of bit line ZBLa is higher than that of bit line BLa. Therefore, the potential difference between bit lines ZBLa and BLa is amplified to power supply potential Vcc with the polarity reverse to the data signal read from memory cell 110. Thus, the pair of bit lines BLa, ZBLa are amplified with the polarity reverse to the data signal read from memory cell 110, and attain L level and H level respectively.

As described above, in the DRAM of the second embodiment, when word line WLb and bit line BLb are short-circuited on the side of memory cell array b, the effect thereof will be communicated to the side of memory cell array a. Therefore, in the DRAM of the second embodiment, a defective bit line is detected not only on the side of memory cell array b where the short-circuit has been caused but also on the side of memory cell array a through a test.

Thus, according to the second embodiment, with a delay of the bit line isolation signal by the internal delay circuit, the effect of the short-circuit of the word line and the bit line caused on the side of one memory cell array will be communicated to the other memory cell array, and the defective bit line on the opposite sides of the shared sense amplifier can be detected.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device, comprising:
a first memory cell array including
a first memory cell group arranged in matrix,
a first word line group arranged corresponding to a row of said first memory cell group and each having a memory cell in a corresponding row connected, and
a first bit line pair arranged corresponding to a column of said first memory cell group and each having a memory cell in a corresponding column connected;
a second memory cell array including
a second memory cell group arranged in matrix,
a second word line group arranged corresponding to a row of said second memory cell group and each having a memory cell in a corresponding row connected, and
a second bit line pair arranged corresponding to a column of said second memory cell group and each having a memory cell in a corresponding column connected;
a sense amplifier shared by said first and second bit line pairs;
a bit line equalizing circuit initializing a potential of said first and second bit line pairs;
a first isolating gate circuit switching a connected/isolated state between said first bit line pair and said sense amplifier;
a second isolating gate circuit switching a connected/isolated state between said second bit line pair and said sense amplifier; and
a control circuit allowing isolation of said first or second bit line pair from said sense amplifier by said first or second isolating gate circuit a certain time after a bit line equalizing operation by said bit line equalizing circuit is cancelled.

2. The semiconductor device according to claim 1, wherein said control circuit includes a timing circuit controlling a timing of isolation of said first or second bit line pair from said sense amplifier by said first or second isolating gate circuit using an external signal so that isolation is carried out a certain time after the bit line equalizing operation by said bit line equalizing circuit is cancelled.

3. The semiconductor device according to claim 1, wherein
said control circuit includes a delay circuit setting a delay for a certain time period between isolation of said first or second bit line pair from said sense amplifier by said first or second isolating gate circuit and cancellation of the bit line equalizing operation by said bit line equalizing circuit.
